(19) United States
(12) Patent Application Publication
(10) Pub. No.: US 2024/0292688 A1
(43) Pub. Date: Aug. 29, 2024

(54) DISPLAY SUBSTRATE, DISPLAY BACKPLANE AND DISPLAY PANEL

(71) Applicants: Hefei Xinsheng Optoelectronics Technology Co., Ltd., Hefei, Anhui (CN); BOE Technology Group Co., Ltd., Beijing (CN)

(72) Inventors: Jun WANG, Beijing (CN); Jun CHENG, Beijing (CN); Haitao WANG, Beijing (CN); Tongshang SU, Beijing (CN); Yongchao HUANG, Beijing (CN); Jingang FANG, Beijing (CN); Liu ZHANG, Beijing (CN); Shengli LIU, Beijing (CN); Hongzheng WANG, Beijing (CN)

(21) Appl. No.: 18/026,752

(22) PCT Filed: Jun. 21, 2022
(86) PCT No.: PCT/CN2022/100063

§ 371 Date: Mar. 16, 2023

(51) Int. Cl. H10K 59/131; H10K 59/80; H10K 102/00; H10K 102/10

(52) U.S. Cl. CPC H10K 59/131; H10K 59/80517; H10K 59/80518; H10K 59/873; H10K 2102/103; H10K 2102/3026

(57) ABSTRACT

Provided is a display substrate, including: a base, a first signal line, a second signal line, and a first electrode. The first signal line, the second signal line and the first electrode are located on the base and sequentially arranged away from the base, and are insulated from each other; orthographic projections of the first signal line and the second signal line on the base at least partially overlap, an orthographic projection of the first electrode partially overlaps with an overlapping region in which the orthographic projections of the first signal line and the second signal line on the base overlap; an opening is provided in at least a partial region of the first electrode, with the orthographic projection thereof on the base overlaps with the overlapping region in which the orthographic projections of the first signal line and the second signal line on the base overlap with each other.

### TECHNICAL FIELD

The present disclosure relates to the field of display technology, and particularly relates to a display substrate, a display backplane and a display panel.

### BACKGROUND

Organic Light-Emitting Diode (OLED) display devices have gained widespread attention because of their characteristics of self-luminescence, high brightness, wide viewing angle, high contrast, flexibility, and low power consumption, and have begun to gradually replace conventional liquid crystal display (LCD) devices as a new generation of display devices, and are widely applied to mobile phone screens, computer monitors, full-color televisions, and the like. The OLED display panels in the related art may be classified into a top-emission type and a bottom-emission type according to light emitting manners thereof.

### SUMMARY

In a first aspect, an embodiment of the present disclosure provides a display substrate, including: a base, a first signal line, a second signal line, and a first electrode, where
the first signal line, the second signal line and the first electrode are located on the base and sequentially arranged away from the base, and the first signal line, the second signal line and the first electrode are insulated from each other;
orthographic projections of the first signal line and the second signal line on the base at least partially overlap with each other, an orthographic projection of the first electrode on the base partially overlaps with an overlapping region in which the orthographic projections of the first signal line and the second signal line on the base overlap with each other; and an opening is provided in at least a partial region of the first electrode, with the orthographic projection thereof on the base overlaps with the overlapping region in which the orthographic projections of the first signal line and the second signal line on the base overlap with each other.

In some implementations, the first signal line include a body line, and the body line is spatially intersected with the second signal line; and an orthographic projection of the opening on the base covers a spatial intersection position at which the body line and the second signal line are spatially intersected.
In some implementations, the first signal line further includes a spare line, the spare line is located in the same film layer as the body line, and a part of the body line is connected in parallel with the spare line;
the spare line is spatially intersected with the second signal line; and
the orthographic projection of the opening on the base further covers a spatial intersection position at which the spare line is spatially intersected with the second signal line.

In some implementations, multiple first signal lines parallel to each other are provided, a distance between at least two adjacent first signal lines is smaller than a width of the opening along a direction in which the two adjacent first signal lines are arranged; and
the orthographic projection of the opening on the base covers orthographic projections of parts of the two adjacent first signal lines and a part of a spacing between the two adjacent first signal lines on the base.

In some implementations, multiple second signal lines parallel to each other are provided, a distance between at least two adjacent second signal lines is smaller than a width of the opening along a direction in which the two adjacent second signal lines are arranged; and the orthographic projection of the opening on the base covers orthographic projections of parts of the two adjacent second signal lines and a part of a spacing between the two adjacent second signal lines on the base.

In some implementations, multiple first electrodes are provided, and the multiple first electrodes are arranged in an array:
each of at least part of the first electrodes is provided with the opening;
an area of the orthographic projection of the opening in the first electrode on the base occupies 1/30 to 1/20 of an Area of the Orthographic Projection of the First Electrode on the base.

In some implementations, distances, each along an extending direction in which the first signal line extends, between any two openings, adjacent to each other along the extending direction in which the first signal line extends, in the first electrodes in two adjacent columns along an extending direction in which the second signal line extends, are not equal.

In some implementations, at least one opening exposes parts of two adjacent second signal lines; and/or
at least one opening exposes parts of two adjacent first signal lines.

In some implementations, the first signal line includes a scanning signal line or a light-emitting control signal line; and
the second signal line includes a data signal line, a power signal line, and a sensing signal line.

In a second aspect, an embodiment of the present disclosure provides a display backplane, which includes the above-mentioned display substrate, where
a filling structure is arranged in the opening of the first electrode in the display substrate, and an orthographic projection of the filling structure on the base in the display substrate is coincident with an orthographic projection of the opening on the base.

In some implementations, a surface of the filling structure away from the base is flush with a surface of the first electrode away from the base.

In some implementations, the filling structure includes a transparent conductive layer and/or a transparent insulating layer; and
the transparent insulating layer and the transparent conductive layer are sequentially arranged in a direction away from the base.

In a third aspect, an embodiment of the present disclosure provides a display panel, which includes the above-mentioned display backplane.

In some implementations, the display panel further includes a light-emitting functional layer and a second electrode on the display backplane, with the light-emitting functional layer and the second electrode being sequentially arranged in a direction away from the first electrode in the display backplane, and orthographic projections of the light-emitting functional layer and the second electrode on the display backplane respectively covering the first electrode and the opening in the first electrode; where
the second electrode is made of an opaque conductive material;
or, the second electrode is made of a light-transmitting conductive material;
the first electrode further includes an opaque conductive material layer located on a side, away from the base in the display backplane, of a light-transmitting conductive material layer of the first electrode.

In some implementations, the display panel further includes a plurality of pixel areas, each of the pixel areas including a transparent sub-area and a display sub-area;
the first electrode, the light-emitting functional layer and the second electrode are sequentially staked to form a light-emitting device, with the light-emitting device being located in the display sub-area;
the first signal line and the second signal line in the display backplane are located in the display sub-area; and
the base extends from the display sub-area to the transparent sub-area.

In a fourth aspect, an embodiment of the present disclosure provides a display device, which includes the above-mentioned display panel.

In a fifth aspect, an embodiment of the present disclosure provides a method for manufacturing a display substrate, including:
sequentially forming a first signal line, a second signal line and a pattern of a first electrode on a base;
where the first signal line, the second signal line, and the first electrode are insulated from each other, orthographic projections of the first signal line and the second signal line on the base at least partially overlap with each other, an orthographic projection of the first electrode on the base partially overlaps with an overlapping region in which the orthographic projections of the first signal line and the second signal line on the base overlap with each other;
forming the pattern of the first electrode includes: forming, through a patterning process, an opening in at least a partial region of the first electrode, with the orthographic projection thereof on the base overlaps with the overlapping region in which the orthographic projections of the first electrode and the first signal line on the base overlap with each other.

In a sixth aspect, an embodiment of the present disclosure provides a method for manufacturing a display backplane, including the method for manufacturing the display substrate; where
the method for manufacturing the display backplane further includes: forming a filling structure in the opening of the first electrode of the display substrate, an orthographic projection of the filling structure on the base in the display substrate is coincident with an orthographic projection of the opening on the base.

In some implementations, the forming a filling structure includes: forming an insulating layer and/or a conductive layer; where
the insulating layer and the conductive layer are sequentially formed in the opening.

### BRIEF DESCRIPTION OF DRAWINGS

The accompanying drawings are included to provide a further understanding of the embodiments of the present disclosure, and are incorporated in and constitute a part of this specification, illustrate embodiments of the disclosure and together with the description serve to explain the principles of the present disclosure and are not to limit the present disclosure. The above and other features and advantages will become more apparent to those skilled in the art by describing in detail exemplary embodiments with reference to the attached drawings.

FIG. 1 is a schematic structural diagram of an exemplary display substrate.

FIG. 2 is a schematic cross-sectional view of the structure of FIG. 1 taken along a cutting line AA′.

FIG. 3 is a schematic diagram of an exemplary pixel driving circuit.

FIG. 4 is a schematic diagram of another exemplary pixel driving circuit.

FIG. 5 is a schematic top view of a partial structure of a display substrate prepared with a pixel driving circuit and an anode in the related art.

FIG. 6 is a schematic top view of a partial structure of a display substrate according to an embodiment of the present disclosure.

FIG. 7 is a schematic cross-sectional view of the structure of FIG. 6 taken along a cutting line BB′.

FIG. 8 is a schematic top view of a partial structure of a display substrate according to an embodiment of the present disclosure.

FIG. 9 is a schematic cross-sectional view of the structure of FIG. 8 taken along a cutting line CC′.

FIG. 10 is a schematic top view of a partial structure of a display substrate according to an embodiment of the present disclosure.

FIG. 11 is a schematic top view of a partial structure of a display substrate according to an embodiment of the present disclosure.

FIG. 12 is a schematic top view of a partial structure of a display substrate according to an embodiment of the present disclosure.

### DETAIL DESCRIPTION OF EMBODIMENTS

In order to make those skilled in the art better understand the technical solutions of the embodiments of the present disclosure, the following describes a display substrate, a display backplane, and a display panel provided in the embodiments of the present disclosure in further detail with reference to the accompanying drawings and implementations.

The embodiments of the present disclosure will be described more fully hereinafter with reference to the accompanying drawings, but the embodiments shown may be embodied in different forms and should not be construed as limited to the embodiments set forth herein. Rather, these embodiments are provided so that this disclosure will be thorough and complete, and will fully convey the scope of the disclosure to those skilled in the art.

The embodiments of the present disclosure are not limited to the embodiments shown in the drawings, but include modifications of configurations formed based on a manufacturing process. Thus, regions illustrated in the drawings have schematic properties, and shapes of the regions shown in the drawings illustrate specific shapes of the regions, but are not intended to be limiting.

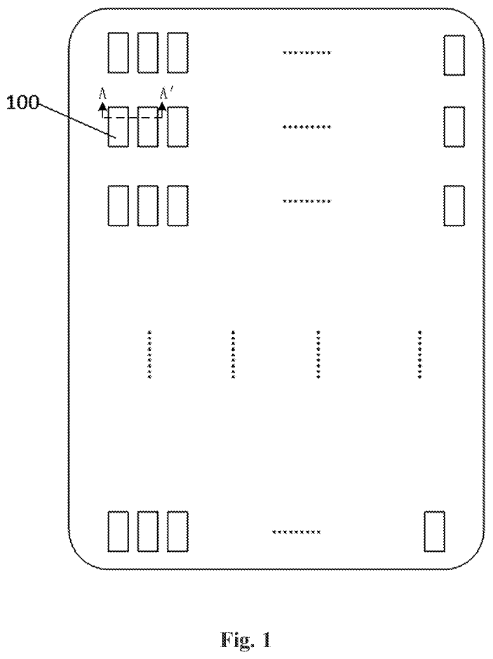

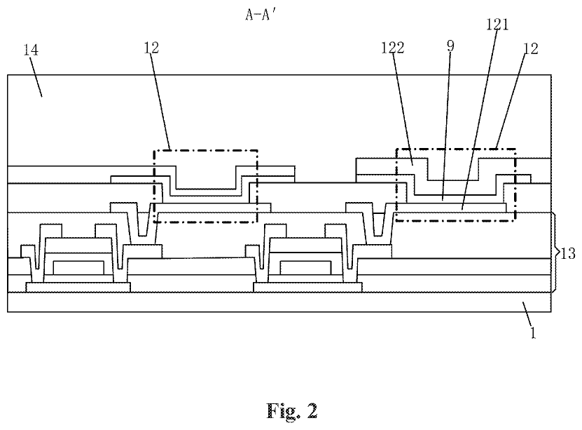

FIG. 1 is a schematic structural diagram of an exemplary display substrate in the related art, FIG. 2 is a schematic cross-sectional view of the structure of FIG. 1 taken along a cutting line AA′, as shown in FIGS. 1 and 2, the display substrate includes a base 1 and a plurality of pixel units 100 arranged in an array on the base 1, where each pixel unit 100 includes a pixel driving circuit 13 and a light-emitting device 12. As shown in FIG. 2, the pixel driving circuit 13, the light-emitting device 12, and an encapsulation layer 14 encapsulating the light-emitting device 12 are sequentially disposed on the base 1. The light-emitting device 12 includes an anode 121, a light-emitting functional layer 9, and a cathode 122, which are sequentially disposed in a direction away from the base. For a top-emission type OLED light-emitting device, the anode 121 is generally formed by stacking a first light-transmissive ITO (indium tin oxide) layer, an opaque silver film layer and a second light-transmissive ITO layer, and the anode 121 can reflect light emitted from the light-emitting device 12 to a side of the display panel away from the base 1, so as to realize top emission of the OLED light-emitting device. For a bottom-emission type OLED light-emitting device, the cathode 122 is usually made of an opaque conductive material (such as silver or copper), and the cathode 122 can reflect the light emitted from the light-emitting device 12 to a side of the display panel where the base 1 is located, so as to realize bottom emission of the OLED light-emitting device.

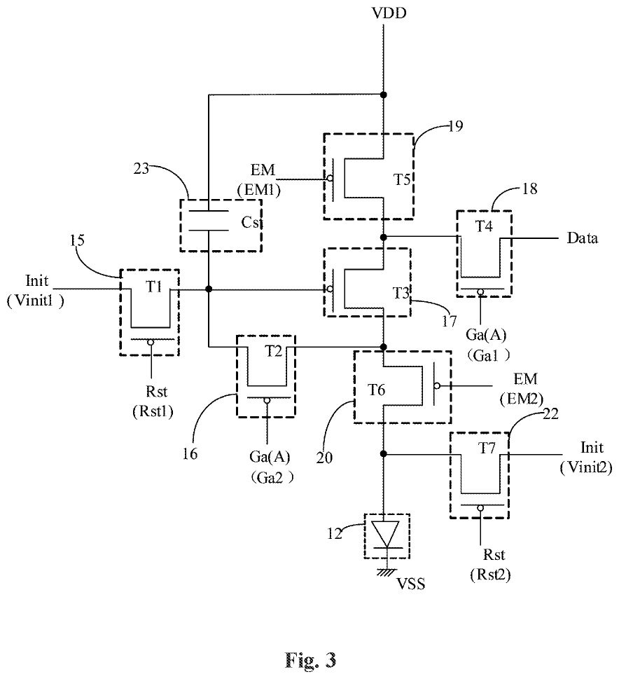

In the related art, FIG. 3 is a schematic diagram of an exemplary pixel driving circuit, the pixel driving circuit in each pixel unit may include: a first reset sub-circuit 15, a threshold compensation sub-circuit 16, a driving sub-circuit 17, a data writing sub-circuit 18, a first light-emitting control sub-circuit 19, a second light-emitting control sub-circuit 20, a second reset sub-circuit 22, and a storage sub-circuit 23.

The first reset sub-circuit 15 is connected to a control terminal of the driving sub-circuit 17 and is configured to reset the control terminal of the driving sub-circuit 17 under the control of a first reset signal. The threshold compensation sub-circuit 16 is electrically connected to the control terminal and a second terminal of the driving sub-circuit 17, respectively, and is configured to compensate a threshold of the driving sub-circuit 17. The data writing sub-circuit 18 is electrically connected to a first terminal of the driving sub-circuit 17, and is configured to write a data signal to the storage sub-circuit 23 under the control of a scan signal. The storage sub-circuit 23 is electrically connected to the control terminal of the driving sub-circuit 17 and a first power signal line VDD, respectively, and is configured to store the data signal. The first light-emitting control sub-circuit 19 is connected to the first power signal line VDD and the first terminal of the driving sub-circuit 17, respectively, and is configured to switch on or switch off a connection between the driving sub-circuit 17 and the first power signal line VDD, and the second light-emitting control sub-circuit 20 is electrically connected to the second terminal of the driving sub-circuit 17 and a first electrode of the light-emitting device 12, respectively, and is configured to switch on or switch off a connection between the driving sub-circuit 17 and the light-emitting device 12. The second reset sub-circuit 22 is electrically connected to the first electrode of the light-emitting device 12 and is configured to reset the control terminal of the driving sub-circuit 17 and the first electrode of the light-emitting device 12 under the control of a second reset control signal.

Referring to FIG. 3, the first reset sub-circuit 15 includes a first reset transistor T1, the threshold compensation sub-circuit 16 includes a threshold compensation transistor T2, the driving sub-circuit 17 includes a driving transistor T3, the control terminal of the driving sub-circuit 17 includes a control electrode of the driving transistor T3, the first terminal of the driving sub-circuit 17 includes a first electrode of the driving transistor T3, and the second terminal of the driving sub-circuit 17 includes a second electrode of the driving transistor T3. The data writing sub-circuit 18 includes a data writing transistor T4, the storage sub-circuit 23 includes a storage capacitor Cst, the first light-emitting control sub-circuit 19 includes a first light-emitting control transistor T5, the second light-emitting control sub-circuit 20 includes a second light-emitting control transistor T6, and the second reset sub-circuit 22 includes a second reset transistor T7.

Referring to FIG. 3, a drain of the data writing transistor T4 is electrically connected to a source of the driving transistor T3, a source of the data writing transistor T4 is configured to be electrically connected to the data signal line Data to receive the data signal, and a gate of the data writing transistor T4 is configured to be electrically connected to a first scanning signal line Ga1 to receive a scanning signal: a second electrode plate of the storage capacitor Cst is electrically connected to the first power signal line VDD, and a first electrode plate of the storage capacitor Cst is electrically connected to a gate of the driving transistor T3: a source of the threshold compensation transistor T2 is electrically connected to the gate of the driving transistor T3, a drain of the threshold compensation transistor T2 is electrically connected to a drain of the driving transistor T3, and a gate of the threshold compensation transistor T2 is configured to be electrically connected to a second scanning signal line Ga2 to receive a compensation control signal: a source of the first reset transistor T1 is configured to be electrically connected to a first reset power terminal Vinit1 to receive the first reset signal, a drain of the first reset transistor T1 is electrically connected to the gate of the driving transistor T3, and a gate of the first reset transistor T1 is configured to be electrically connected to a first reset control signal line Rst1 to receive a first reset control signal: a drain of the second reset transistor T7 is configured to be electrically connected to the first reset power terminal Vinit1 to receive the first reset signal, a source of the second reset transistor T7 is electrically connected to the first electrode of the light-emitting device 12, and a gate of the second reset transistor T7 is configured to be electrically connected to a second reset control signal line Rst2 to receive a second reset control signal, a source of the first light-emitting control transistor T5 is electrically connected to the first power signal line VDD, a drain of the first light-emitting control transistor T5 is electrically connected to the source of the driving transistor T3, and a gate of the first light-emitting control transistor T5 is configured to be electrically connected to a first light-emitting control signal line EM1 to receive a first light-emitting control signal: a source of the second light-emitting control transistor T6 is electrically connected to the drain of the driving transistor T3, a drain of the second light-emitting control transistor T6 is electrically connected to the first electrode of the light-emitting device 12, and a gate of the second light-emitting control transistor T6 is configured to be electrically connected to a second light-emitting control signal line EM2 to receive a second light-emitting control signal: a second electrode of the light-emitting device 12 is electrically connected to a second power signal line VSS.

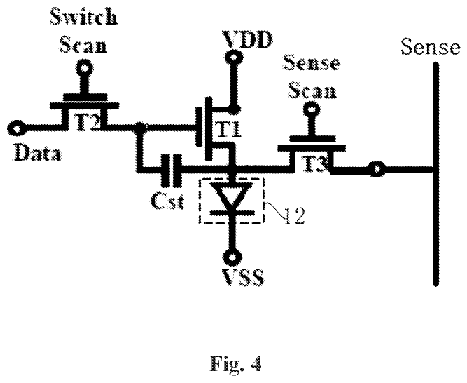

FIG. 4 is a schematic diagram of another exemplary pixel driving circuit in the related art, the pixel driving circuit includes a first transistor T1, a second transistor T2, a third transistor T3, and a storage capacitor Cst, a gate of the first transistor T1 is connected to a drain of the second transistor T2 and a first electrode plate of the storage capacitor Cst, a source of the first transistor T1 is connected to a first power signal line VDD, and a drain of the first transistor T1 is connected to a drain of the third transistor T3, a second electrode plate of the storage capacitor Cst, and an anode of a light-emitting device 12: a cathode of the light-emitting device 12 is connected to a second power signal line VSS: a gate of the second transistor T2 is connected to a switch scanning line Switch Scan, and a source of the second transistor T2 is connected to a data signal line Data: a gate of the third transistor T3 is connected to a sensing scan line Sense Scan, a source of the third transistor T3 is connected to the sensing signal line Sense: the sensing signal line Sense is connected with a data driving circuit (i.e., a data driving chip, Source IC for short). The third transistor T3 is configured to confirm a threshold voltage of the first transistor T1 through the sensing signal line, check a current capability that the first transistor T1 drives a current, and adjust the current capability of the first transistor T1, so that the first transistor T1 always has a constant current capability. The data driving circuit is connected with the data signal line Data and is configured to provide a data driving signal to the data signal line.

Referring to the pixel driving circuits in FIGS. 3 and 4, some of the various signal lines are located in a same layer, some of the signal lines are located in different layers, and the signal lines located in different layers may spatially intersect to form spatial intersection points. For example, the scanning signal line and the gate of the transistor in the pixel driving circuit are usually made of a same material by a single patterning process: the data signal line, the power signal line and the source and drain of the transistor in the pixel driving circuit are usually made of a same material by a single patterning process: the scanning signal line is located in a different layer from the data signal line and the power signal line, and the signal lines in an upper layer and the signal lines in a lower layer form spatial intersection points, the spatial intersection points are easy to cause a short-circuit defect. Meanwhile, adjacent signal lines arranged in the same layer and being relatively close to each other are easily interconnected with each other to cause a short-circuit defect: or, the signal line with a narrow line width is easy to cause a broken-circuit defect therein, the occurrence of the above-mentioned various defects can be found by testing before the preparation of the display substrate is completed, for example, the display substrate prepared with only the pixel driving circuit and the anode is tested to find the short-circuit defect or the broken-circuit defect.

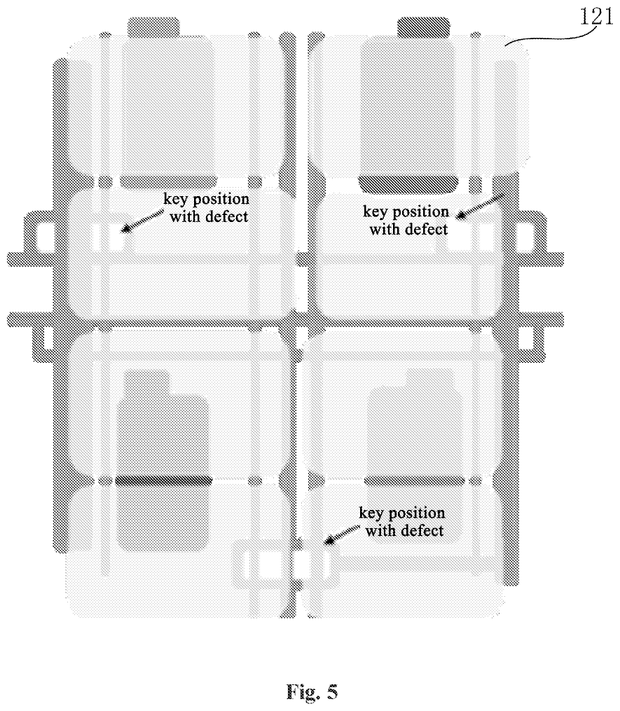

FIG. 5 is a schematic top view of a partial structure of a display substrate prepared with a pixel driving circuit and an anode in the related art, as can be seen from FIG. 5, since the anode 121 of the OLED light-emitting device is overlapped with some key positions (such as spatial intersection points of the signal lines, positions between adjacent signal lines with a short distance therebetween, and positions of the signal lines at which a broken-circuit defect easily occurs) in the pixel driving circuit that are prone to defects, the defect in the pixel driving circuit under the anode 121, which is found after the anode 121 is prepared, cannot be repaired.

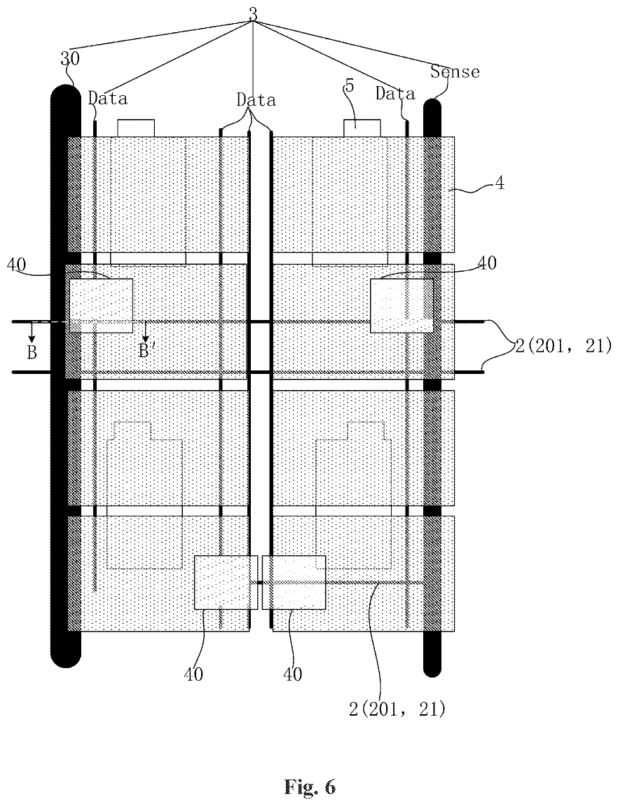

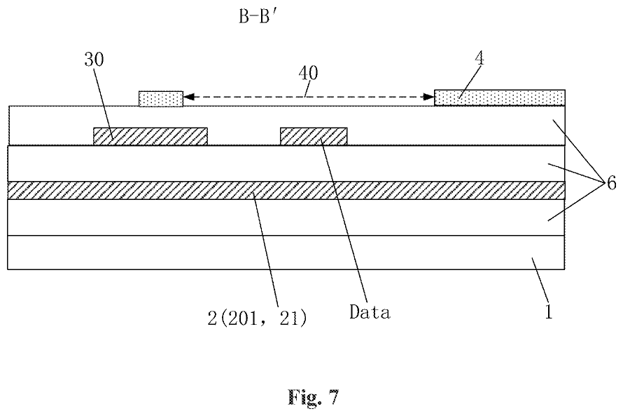

In view of the above problems in the related art, in a first aspect, an embodiment of the present disclosure provides a display substrate, FIG. 6 is a schematic top view of a partial structure of the display substrate in the embodiment of the present disclosure, FIG. 7 is a schematic cross-sectional view of the structure of FIG. 6 taken along a cutting line BB′, where, the display substrate includes: a base 1: a first signal line 2; a second signal line 3; a first electrode 4, the first signal line 2, the second signal line 3 and the first electrode 4 are located on the base 1 and are sequentially arranged in a direction away from the base 1: the first signal line 2, the second signal line 3 and the first electrode 4 are insulated from each other. Orthographic projections of the first signal line 2 and the second signal line 3 on the base 1 at least partially overlap with each other; an orthographic projection of the first electrode 4 on the base 1 partially overlaps with an overlapping region in which the orthographic projections of the first signal line 2 and the second signal line 3 on the base 1 overlap with each other. An opening 40 is provided in at least a partial region of the first electrode 4, with the orthographic projection thereof on the base 1 overlaps with the overlapping region in which the orthographic projections of the first signal line 2 and the second signal line 3 on the base 1 overlap with each other.

In some implementations, an insulating layer 6 is disposed between every adjacent two of the first signal line 2, the second signal line 3 and the first electrode 4, so that the first signal line 2, the second signal line 3 and the first electrode 4 located in different layers are insulated from each other.

In some implementations, referring to FIGS. 6 and 7, the first signal line 2 includes a scanning signal line 21 or a light-emitting control signal line: the second signal line 3 includes a data signal line Data, a power signal line 30, and a sensing signal line Sense.

In some implementations, the first signal line 2 and the second signal line 3 may be any signal lines located in any two different layers, and are not limited to the scanning signal line and the data signal line located in different layers.

In some implementations, the first electrode 4 may be an anode of an OLED light-emitting device, and may also be a pixel electrode of a sub-pixel in a liquid crystal display panel.

In some implementations, the display substrate is an OLED display substrate, the OLED display substrate includes a pixel driving circuit, the pixel driving circuit includes a driving transistor, a source or a drain of the driving transistor is connected to the first electrode 4, a light-blocking metal layer 5 is provided on a side of the driving transistor close to the base 1, and the light-blocking metal layer 5 blocks light from irradiating an active layer of the driving transistor, so as to avoid an increase in leakage current of the driving transistor caused by the light irradiating the active layer, and ensure performance of the driving transistor.

In the embodiment of the present disclosure, due to defects in the manufacturing process or other reasons, the first signal line 2 and the second signal line 3 are prone to short-circuit defects in the overlapping region in which the orthographic projections thereof on the base overlap with each other, a position of the first electrode 4 for forming the opening 40 is a position point at which a short-circuit defect is prone to occur between the first signal line 2 and the second signal line 3, by forming the opening 40 in at least a partial region of the first electrode 4, with the orthographic projection thereof on the base overlaps with the overlapping region in which the orthographic projections of the first signal line 2 and the second signal line 3 on the base overlap with each other, if a short-circuit defect occurs between the first signal line 2 and the second signal line 3, the position point at which the short-circuit defect occurs can be repaired, from a side where the first electrode 4 is located, through the opening 40, thereby ensuring the quality of the display substrate.

In some implementations, the position point at which the short-circuit defect occurs is repaired by laser cutting through the opening 40 from the side where the first electrode 4 is located, so that the two signal lines with the short-circuit defect therebetween are cut off at the position point at which the short-circuit defect occurs, so that the short-circuit defect is eliminated.

In some implementations, referring to FIG. 6, the first signal line 2 includes a body line 201, the body line 201 is spatially intersected with the second signal line 3, an orthographic projection of the opening 40 on the base 1 covers a spatial intersection position at which the body line 201 and the second signal line 3 are spatially intersected.

The body line 201 and the second signal line 3 are prone to a short-circuit defect at the spatial intersection position therebetween, and the short-circuit defect at the spatial intersection position can be conveniently repaired by covering the spatial intersection position, at which the body line 201 and the second signal line 3 are spatially intersected, with the orthographic projection of the opening 40 on the base 1.

In some implementations, referring to FIG. 6, the first signal line 2 includes a scanning signal line 21 (e.g., a gate line), and the second signal line 3 includes a data signal line Data, a power signal line 30, and a sensing signal lines Sense. The scanning signal line 21 respectively intersects with the data signal line Data, the power signal line 30, and the sensing signal line Sense in vertical and horizontal directions to form spatial intersection positions.

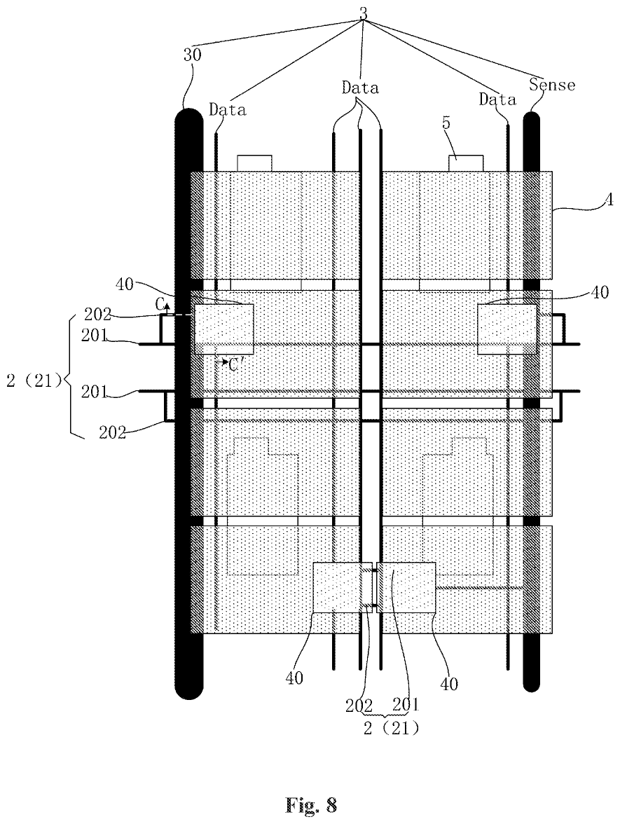

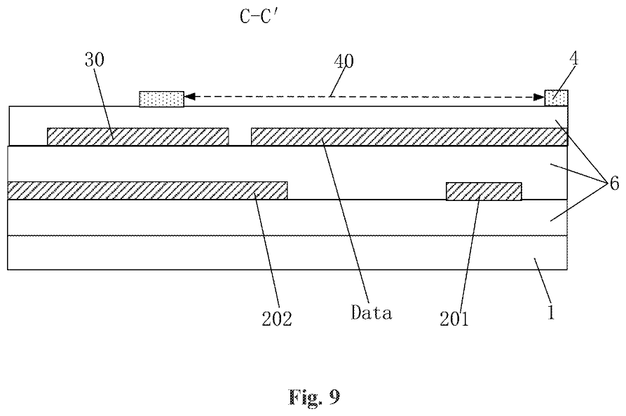

FIG. 8 is a schematic top view of a partial structure of another display substrate in an embodiment of the present disclosure, and FIG. 9 is a schematic cross-sectional view of the structure of FIG. 8 taken along a cutting line CC′, referring to FIGS. 8 and 9, in some implementations, the first signal line 2 further includes a spare line 202, the spare line 202 and the body line 201 are located in a same film layer, and a part of the body line 201 is connected in parallel with the spare line 202. The spare line 202 and the second signal line 3 spatially intersects, the orthographic projection of the opening 40 on the base 1 further covers a spatial intersection position at which the spare line 202 and the second signal line 3 spatially intersects.

The spare line 202 and the second signal line 3 are prone to a short-circuit defect at the spatial intersection position therebetween, and the short-circuit defect at the spatial intersection position can be repaired conveniently by making the orthographic projection of the opening 40 on the base 1 cover the spatial intersection position at which the spare line 202 and the second signal line 3 spatially intersects. The spare line 202 can keep the signal transmitted by the body line 201 to be continuously transmitted through the spare line 202 if the body line 201 is broken due to a fault, and a display failure of the display substrate caused by a loss of the signal is avoided. Similarly, if the spare line 202 is broken due to a fault, the body line 201 can play the same role as described above.

In some implementations, referring to FIG. 8, multiple first signal lines 2 parallel to each other are provided, a distance between at least two adjacent first signal lines 2 is less than a width of the opening 40 along a direction in which the two adjacent first signal lines 2 are arranged, the orthographic projection of the opening 40 on the base 1 covers orthographic projections of parts of the two adjacent first signal lines 2 and a part of a spacing between the two adjacent first signal lines on the base 1.

The distance between the two adjacent first signal lines 2 may be a minimum safety distance between the two adjacent first signal lines 2. If the distance between the two adjacent first signal lines 2 is relatively small, a short-circuit interconnection defect easily occurs between the two first signal lines 2 at certain position points, by forming the opening 40 at a position of the first electrode 4 corresponding to the position point, at which the short-circuit interconnection easily occurs, of the two first signal lines 2, the position point at which the short-circuit interconnection occurs can be conveniently repaired. In addition, if a line width of the first signal line 2 is relatively small, a broken-circuit defect easily occurs in the first signal line 2 at certain positions, by forming the opening 40 at a position of the first electrode 4 corresponding to the position point, at which the broken-circuit defect easily occurs, of the first signal line 2, the position point at which the broken-circuit defect occurs can be conveniently repaired.

In some implementations, the two first signal lines 2 with the short-circuit interconnection defect are cut by laser through the opening 40, and a connection between the two first signal lines 2 at the position point at which the short-circuit interconnection occurs is cut off, and the first signal line 2 with the broken-circuit defect is repaired by laser through the opening 40, so that the first signal line 2 is repaired and kept to be continuous at the position point at which the broken-circuit defect occurred.

In some implementations, referring to FIG. 8, multiple second signal lines 3 parallel to each other are provided, a distance between at least two adjacent second signal lines 3 is less than a width of the opening 40 along a direction in which the two adjacent second signal lines 3 are arranged, and the orthographic projection of the opening 40 on the base 1 covers orthographic projections of parts of the two adjacent second signal lines 3 and a part of a spacing between the two adjacent second signal lines on the base 1.

The distance between the two adjacent second signal lines 3 may be a minimum safety distance between the two second signal lines 3, and if the distance between the two adjacent second signal lines 3 is relatively small, a short-circuit interconnection defect easily occurs between the two second signal lines 3 at certain position points, by forming the opening 40 at a position of the first electrode 4 corresponding to the position point, at which the short-circuit interconnection defect easily occurs, of the two second signal lines 3, the position point at which the short-circuit interconnection defect occurs can be conveniently repaired. In addition, if a line width of the second signal line 3 is relatively small, a broken-circuit defect easily occurs in the second signal line 3 at certain position points, by forming the opening 40 at a position of the first electrode 4 corresponding to the position point, at which the broken-circuit defect easily occurs, of the second signal line 3, the position point at which the broken-circuit occurs can be conveniently repaired.

In some implementations, the two second signal lines 3 with the short-circuit interconnection therebetween are cut by laser through the opening 40, so as to cut off a connection between the two second signal lines 3 at the position point at which the short-circuit interconnection defect occurs: the second signal line 3 with the broken-circuit defect is repaired by laser through the opening 40, so that the second signal line 3 is repaired and kept to be continuous at the position point at which the broken-circuit defect occurs.

In some implementations, referring to FIG. 8, multiple first electrodes 4 are provided, and the multiple first electrodes 4 are arranged in an array; each of at least part of the first electrodes 4 is provided with the opening 40. An area of the orthographic projection of the opening 40 of the first electrode 4 on the base 1 is 1/30 to 1/20 of an area of the orthographic projection of the first electrode 4 on the base 1. With such arrangement, the area of a region of the first electrode 4 occupied by the opening 40 substantially can not affect the display aperture ratio of the display substrate, thereby ensuring that the display substrate can display normally.

In some implementations, referring to FIG. 8, distances, each along an extending direction in which the first signal line extends, between any two openings 40, adjacent to each other along the extending direction in which the first signal line 2 extends, in the first electrodes 4 in two adjacent columns along an extending direction in which the second signal line 3 extends, are not equal. That is, the positions of the openings 40 may be randomly provided according to the position points at which the short-circuit defect is likely to occur between the first signal lines 2 and the second signal lines 3 or the broken-circuit defect is likely to occur in the first signal lines 2 and/or the second signal lines 3.

In some implementations, referring to FIG. 8, at least one opening 40 exposes parts of two second signal lines 3; and/or at least one opening 40 exposes parts of two first signal lines 2.

In some implementations, the first electrode 4 includes a light-transmitting conductive material layer. The first electrode 4, which serves as for example the anode of the OLED light-emitting device, is typically formed by first forming a light-transmissive ITO layer on a side of the pixel driving circuit away from the base 1. In this way, it is facilitated to observe a defect between the first signal line 2 and the second signal line 3 under the first electrode or a defect in each of the first signal line 2 and the second signal line 3 through the first electrode 4, thereby facilitating to repair the defects.

In some implementations, the first electrode 4 may also be made of an opaque conductive material, and since the opening 40 is formed in the first electrode 4 for maintenance, even the first electrode 4 is made of the opaque conductive material, the defect below the first electrode can be observed through the opening 40, which is convenient for maintenance.

Based on the above-mentioned structure of the display substrate, an embodiment of the present disclosure further provides a method for manufacturing the display substrate, including: sequentially forming a first signal line, a second signal line and a pattern of a first electrode on a base; where the first signal line, the second signal line and the first electrode are insulated from each other: orthographic projections of the first signal line and the second signal line on the base at least partially overlap; an orthographic projection of the first electrode on the base is partially overlapped with an overlapping region in which the orthographic projections of the first signal line and the second electrode on the base overlap with each other; the forming the pattern of the first electrode includes: forming, by a patterning process, an opening in at least a partial region of the first electrode, with the orthographic projection thereof on the base overlaps with the overlapping region in which the orthographic projections of the first signal line and the second signal line on the base overlap with each other.

The patterning process includes: depositing and forming a first electrode film layer, coating a photoresist on the first electrode film layer, exposing and developing the photoresist on the first electrode film layer by using a mask plate containing patterns of the first electrode and an opening in the first electrode, and etching and forming the first electrode and the pattern of the opening in the first electrode.

In some implementations, the manufacturing processes of the first signal line and the second signal line are the same as the manufacturing process of the first electrode, and are not described herein again.

According to the display substrate provided by the embodiment of the present disclosure, at least a partial region of the first electrode, with the orthographic projection thereof on the base overlaps with the overlapping region in which the orthographic projections of the first signal line and the second signal line on the base overlap with each other, is provided with the opening, so that, if a short-circuit defect occurs at any position point between the first signal line and the second signal line, the position point at which the short-circuit defect occurs can be repaired through the opening from the side where the first electrode is located, and the quality of the display substrate is ensured.

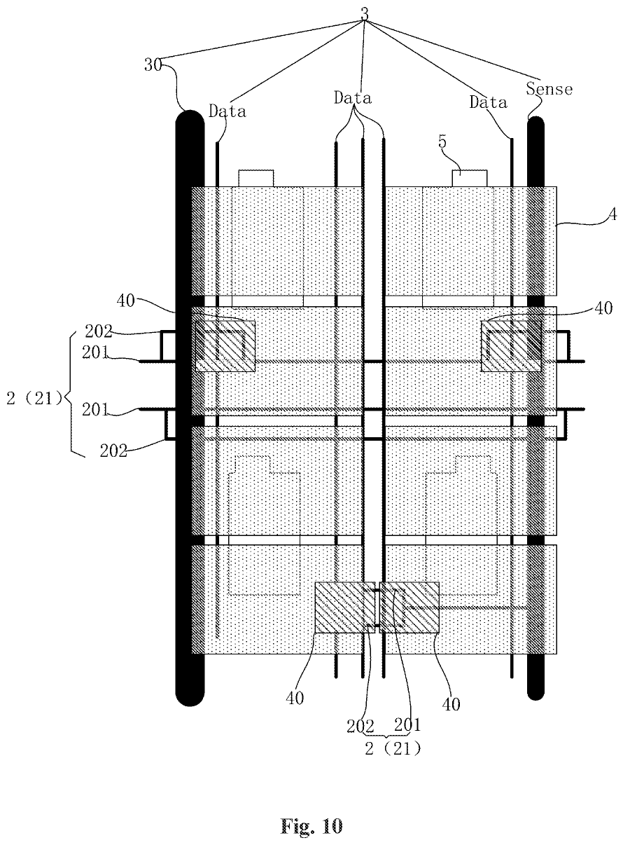

In a second aspect, an embodiment of the present disclosure further provides a display backplane, FIG. 10 is a schematic top view of a partial structure of the display backplane in the embodiment of the present disclosure, and referring to FIG. 10, the display backplane includes the display substrate in the above-mentioned embodiment, where a filling structure 7 is arranged in the opening 40 of the first electrode 4 in the display substrate, and an orthographic projection of the filling structure 7 on the base in the display substrate is coincident with the orthographic projection of the opening 40 on the base.

By providing the filling structure 7 in the opening 40, a flatness of the first electrode 4 can be ensured, facilitating other film layers to be subsequently formed on a side of the first electrode 4 away from the base, and the normal display performance of the display backplane can be ensured.

In some implementations, a surface of the filling structure 7 away from the base is flush with a surface of the first electrode 4 away from the base. With such arrangement, it can further ensure the flatness of the surface of the first electrode 4 away from the base so as to facilitate other film layers to be subsequently formed on the side of the first electrode 4 away from the base, and the normal display performance of the display backplane can be ensured simultaneously.

In some implementations, the filling structure 7 includes a transparent conductive layer and/or a transparent insulating layer; the transparent insulating layer and the transparent conductive layer are sequentially arranged in a direction away from the base. On one hand, the transparent conductive layer in the filling structure 7 can make the region of the first electrode where the opening 40 is located and other regions of the first electrode 4 have the same conductivity, so as to ensure the conductivity of the whole first electrode 4, and further ensure the normal light-emitting performance of the OLED light-emitting device adopting the first electrode 4 as an anode or ensure the normal display performance of a sub-pixel adopting the first electrode 4 as a pixel electrode: on the other hand, if a short-circuit defect occurs at a position point between the first signal line 2 and the second signal line 3 or a broken-circuit defect occurs at a position point of the first signal line 2 and/or the second signal line 3, the position point at which the defect occurs can be repaired by laser through the transparent conductive layer.

In some implementations, the transparent conductive layer is made of a conductive silver adhesive or ITO material, and the transparent insulating layer is made of an organic transparent adhesive such as a photoresist. The filling structure 7 is made of the transparent conductive layer, therefore, on one hand, the filling structure 7 can have the same light transmission performance as the first electrode 4 which can transmit light, so that the defect between the first signal line 2 and the second signal line 3 under the filling structure 7 or the defects in the first signal line 2 and the second signal line 3 under the filling structure 7 can be conveniently observed through the first electrode 4 and the opening 40 in the first electrode 4, and the defects can be conveniently repaired, on the other hand, if the short-circuit defect occurs at a position point between the first signal line 2 and the second signal line 3 or the broken-circuit defect occurs at a position point of the first signal line 2 and/or the second signal line 3, the position point at which the defect occurs can be repaired by laser through the transparent conductive layer and/or the transparent insulating layer.

In some implementations, the filling structure 7 may also be opaque. For example, for a top-emission type OLED light-emitting device adopting the first electrode 4 as an anode, the first electrode 4 and the filling structure 7 filled in the opening 40 each include an opaque conductive film layer so as to reflect light emitted from the OLED light-emitting device, thereby implementing a top-emission display. In this case, however, the short-circuit defect between the first signal line 2 and the second signal line 3 under the first electrode 4 or the broken-circuit defects in the first signal line 2 and the second signal line 3 under the first electrode 4 can only be repaired before the filling structure 7 is provided in the opening 40, and after the filling structure 7 is provided in the opening 40, the laser cannot penetrate the filling structure 7 for repairing the defect because the filling structure 7 is opaque.

Based on the above-mentioned structure of the display backplane, an embodiment of the present disclosure further provides a method for manufacturing the display backplane, which includes the method for manufacturing the display substrate in the above-mentioned embodiment, and the method for manufacturing the display backplane further includes: forming a filling structure in the opening in the first electrode of the display substrate, where an orthographic projection of the filling structure on the base in the display substrate is coincident with the orthographic projection of the opening on the base.

In some implementations, the forming the filling structure includes: forming an insulating layer and/or a conductive layer, where the insulating layer and the conductive layer are sequentially formed in the opening.

In some implementations, the conductive layer is made of a conductive silver adhesive: the insulating layer is made of an organic transparent adhesive such as a photoresist. The insulating layer and the conductive layer are respectively formed by spraying a transparent adhesive in the opening through a nozzle of an adhesive spraying equipment, such that the opening is enclosed.

According to the display backplane provided by the embodiment of the present disclosure, by adopting the display substrate in the above-mentioned embodiment, if a short-circuit defect occurs at a position point between the first signal line and the second signal line in the display backplane, the position point at which the short-circuit defect occurs can be repaired through the opening from the side where the first electrode of the display backplane is located, so that the quality of the display substrate is ensured; the display backplate can fill up the opening of first electrode by providing the filling structure in the opening to ensure the flatness of the whole film layer of the first electrode, so that other flat film layers can be subsequently formed on the side of the first electrode away from the base, and the normal display performance of the display backplate can also be ensured.

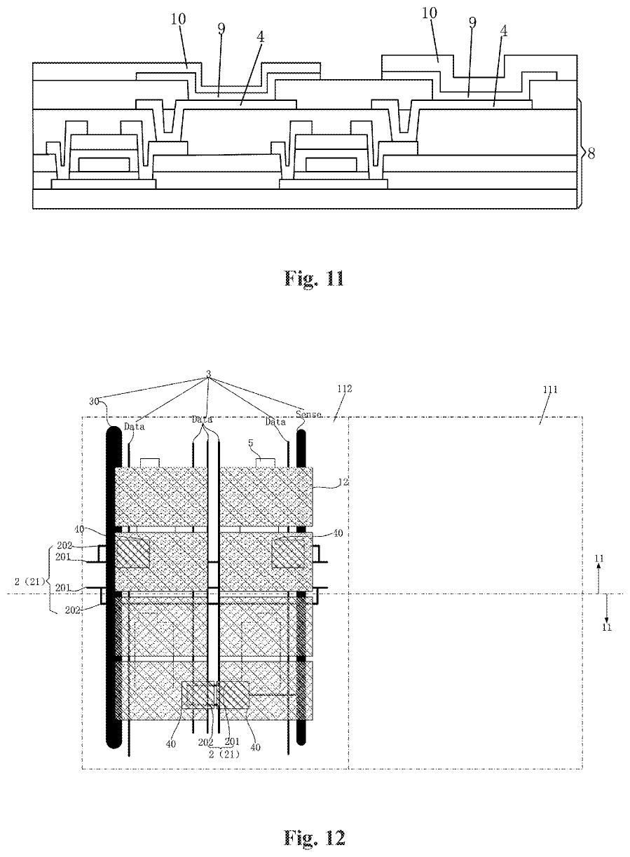

In a third aspect, an embodiment of the present disclosure further provides a display panel, FIG. 11 is a schematic cross-sectional view of a partial structure of the display panel in the embodiment of the present disclosure, referring to FIG. 11, the display panel includes the display backplane 8 in the above-mentioned embodiment.

In some implementations, referring to FIG. 11, the display panel further includes a light-emitting functional layer 9 and a second electrode 10, which are located on the display backplane 8, and the light-emitting functional layer 9 and the second electrode 10 are sequentially arranged in a direction away from the first electrode 4 in the display backplane 8; and orthographic projections of the light-emitting functional layer 9 and the second electrode 10 on the display backplane 8 cover the first electrode 4 and the opening in the first electrode 4, respectively. A structure in which the first electrode 4, the light emitting functional layer 9 and the second electrode 10 are stacked may form a light-emitting device.

In some implementations, the second electrode 10 is made of an opaque conductive material, the first electrode 4 is a light-transmitting conductive material layer, with such configurations, the light emitted from the light-emitting device is reflected by the second electrode 10 and then emitted from a side where the display backplane 8 is located, thereby implementing a bottom-emission type light-emitting device.

In some implementations, the second electrode 10 is made of a light-transmitting conductive material, the first electrode 4 includes, in addition to the transparent conductive material layer, an opaque conductive material layer, and the opaque conductive material layer is located on a side, away from the base 1 in the display backplane 8, of the transparent conductive material layer. With such arrangement, light emitted from the light-emitting device is reflected by the first electrode 4 and then emitted from a side where the second electrode 10 is located, thereby implementing a top-emission type light-emitting device.

FIG. 12 is a schematic top view of a partial structure of the display panel in an embodiment of the present disclosure, in some implementations, referring to FIG. 12, the display panel includes a plurality of pixel areas 11, each pixel area 11 includes a transparent sub-area 111 and a display sub-area 112: the first electrode, the light-emitting functional layer and the second electrode are sequentially stacked to form a light-emitting device 12, the light-emitting device 12 is located in the display sub-area 112, the first signal line 2 and the second signal line 3 in the display backplane are located in the display sub-area 112, and the base extends from the display sub-area 112 to the transparent sub-area 111.

In the display panel, by configuring each pixel area 11 to include the transparent sub-area 111 and the display sub-area 112, the light-emitting device 12 and a pixel driving circuit (including transistors and various signal lines) for driving the light-emitting device 12 to emit light are provided in the display sub-area 112, and only the transparent insulating layer, such as the base, the inorganic insulating layer and the organic insulating layer, is provided in the transparent sub-area 111, so that a transmissive display of the display panel can be implemented. The display panel may be a transparent display panel with a relatively large size (e.g., 55 inch).

According to the display panel provided in the embodiment of the present disclosure, by adopting the above-mentioned display backplane, if a short-circuit defect occurs at a position point between the first signal line and the second signal line in the display backplane, the position point at which the short-circuit defect occurs can be repaired through the opening from the side where the first electrode of the display backplane is located, so that the quality of the display backplane is ensured, and the quality of the display panel is ensured.

In a fourth aspect, an embodiment of the present disclosure further provides a display device, which includes the display panel in the foregoing embodiment.

By adopting the display panel in the above-mentioned embodiment, the short-circuit defect in the display device can be repaired in time, so that the quality of the display device is ensured.

The display device provided by the embodiment of the present disclosure may be any product or component with a display function, such as an OLED panel, an OLED television, an OLED billboard, an LCD panel, an LCD television, a display, a mobile phone, and a navigator.

It will be understood that the above embodiments are merely exemplary embodiments employed to illustrate the principles of the present disclosure, and the present disclosure is not limited thereto. It will be apparent to those skilled in the art that various improvements and modifications can be made without departing from the spirit and scope of the present disclosure, and these improvements and modifications are to be considered within the scope of the present disclosure.

1. A display substrate, comprising: a base, a first signal line, a second signal line, and a first electrode, wherein
the first signal line, the second signal line and the first electrode are located on the base and sequentially arranged in a direction away from the base, and the first signal line, the second signal line and the first electrode are insulated from each other;
orthographic projections of the first signal line and the second signal line on the base at least partially overlap with each other, an orthographic projection of the first electrode on the base partially overlaps with an overlapping region in which the orthographic projections of the first signal line and the second signal line on the base overlap with each other; and
an opening is provided in at least a partial region of the first electrode, with the orthographic projection thereof on the base overlaps with the overlapping region in which the orthographic projections of the first signal line and the second signal line on the base overlap with each other.

2. The display substrate of claim 1, wherein the first signal line comprises a body line, and the body line is spatially intersected with the second signal line; and
an orthographic projection of the opening on the base covers a spatial intersection position at which the body line and the second signal line are spatially intersected.

3. The display substrate of claim 2, wherein the first signal line further comprises a spare line, the spare line is located in the same film layer as the body line, and a part of the body line is connected in parallel with the spare line;
the spare line is spatially intersected with the second signal line; and
the orthographic projection of the opening on the base further covers a spatial intersection position at which the spare line is spatially intersected with the second signal line.

4. The display substrate of claim 1, wherein multiple first signal lines parallel to each other are provided, a distance between at least two adjacent first signal lines is smaller than a width of the opening along a direction in which the two adjacent first signal lines are arranged; and
the orthographic projection of the opening on the base covers orthographic projections of parts of the two adjacent first signal lines and a part of a spacing between the two adjacent first signal lines on the base.

5. The display substrate of claim 1, wherein multiple second signal lines parallel to each other are provided, a distance between at least two adjacent second signal lines is smaller than a width of the opening along s direction in which the two adjacent second signal lines are arranged; and
the orthographic projection of the opening on the base covers orthographic projections of parts of the two adjacent second signal lines and a part of a spacing between the two adjacent second signal lines on the base.

6. The display substrate of claim 1, wherein multiple first electrodes are provided, and the multiple first electrodes are arranged in an array;
each of at least part of the first electrodes is provided with the opening;
an area of the orthographic projection of the opening in the first electrode on the base is 1/30 to 1/20 of an area of the orthographic projection of the first electrode on the base.

7. The display substrate of claim 6, wherein distances, each along an extending direction in which the first signal line extends, between any two openings, adjacent to each other along the extending direction in which the first signal line extends, in the first electrodes in two adjacent columns along an extending direction in which the second signal line extends, are not equal.

8. The display substrate of claim 6, wherein at least one opening exposes parts of two adjacent second signal lines; and/or
at least one opening exposes parts of two adjacent first signal lines.

9. The display substrate of claim 1, wherein the first signal line comprises a scanning signal line or a light-emitting control signal line; and
the second signal line comprises a data signal line, a power signal line, and a sensing signal line.

10. A display backplane, comprising the display substrate of claim 1; wherein
a filling structure is arranged in the opening of the first electrode in the display substrate, and an orthographic projection of the filling structure on the base in the display substrate is coincident with an orthographic projection of the opening on the base.

11. The display backplane of claim 10, wherein a surface of the filling structure away from the base is flush with a surface of the first electrode away from the base.

12. The display backplane of claim 11, wherein the filling structure comprises a transparent conductive layer and/or a transparent insulating layer; and
the transparent insulating layer and the transparent conductive layer are sequentially arranged in a direction away from the base.

13. A display panel, comprising the display backplane of claim 10.

14. The display panel of claim 13, further comprising a light-emitting functional layer and a second electrode on the display backplane, with the light-emitting functional layer and the second electrode being sequentially arranged in a direction away from the first electrode in the display backplane, and orthographic projections of the light-emitting functional layer and the second electrode on the display backplane respectively covering the first electrode and the opening in the first electrode; wherein
the second electrode is made of an opaque conductive material;
or, the second electrode is made of a light-transmitting conductive material;
the first electrode further comprises an opaque conductive material layer located on a side, away from the base in the display backplane, of a light-transmitting conductive material layer of the first electrode.

15. The display panel of claim 14, further comprising a plurality of pixel areas, each of the pixel areas comprising a transparent sub-area and a display sub-area;
the first electrode, the light-emitting functional layer and the second electrode are sequentially staked to form a light-emitting device, with the light-emitting device being located in the display sub-area;
the first signal line and the second signal line in the display backplane are located in the display sub-area; and
the base extends from the display sub-area to the transparent sub-area.

16. The display substrate of claim 2, wherein the first signal line comprises a scanning signal line or a light-emitting control signal line; and
the second signal line comprises a data signal line, a power signal line, and a sensing signal line.

17. The display substrate of claim 3, wherein the first signal line comprises a scanning signal line or a light-emitting control signal line; and
the second signal line comprises a data signal line, a power signal line, and a sensing signal line.

18. The display substrate of claim 4, wherein the first signal line comprises a scanning signal line or a light-emitting control signal line; and
the second signal line comprises a data signal line, a power signal line, and a sensing signal line.

19. The display substrate of claim 2, wherein multiple first electrodes are provided, and the multiple first electrodes are arranged in an array;
each of at least part of the first electrodes is provided with the opening;
an area of the orthographic projection of the opening in the first electrode on the base is 1/30 to 1/20 of an area of the orthographic projection of the first electrode on the base.

20. The display substrate of claim 3, wherein multiple first electrodes are provided, and the multiple first electrodes are arranged in an array;
each of at least part of the first electrodes is provided with the opening;
an area of the orthographic projection of the opening in the first electrode on the base is 1/30 to 1/20 of an area of the orthographic projection of the first electrode on the base.
